(19) United States
(12) Patent Application Publication
(10) Pub. No.: US 2002/0197780 A1
(43) Pub. Date: Dec. 26, 2002

(54) Method for forming a metal oxide semiconductor type field effect transistor

(75) Inventors: Han-Chao Lai, Taichung (TW); Hung-Sui Lin, Tainan (TW); Tao-Cheng Lu, Kaohsiung (TW)

Correspondence Address: Benjamin J. Hauptman, LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/888,494

(22) Filed: Jun. 26, 2001

(51) Int. Cl. H01L 21/336; H01L 21/8234; H01L 21/8238; H01L 21/4763

(52) U.S. Cl. 438/197; 438/212; 438/630

(57) ABSTRACT

This invention relates to a method for forming a metal oxide semiconductor type field effect transistor (MOSFET), more particularly, to the method for forming the MOSFET by forming a gate and a spacer in a trench. The present invention is used to form the gate and the spacer of the MOSFET in the trench which is preformed in the substrate to reduce the junction depth of the source/drain region. The present invention also can reduce the defects in the drain induced barrier lowering and the punch-through leakage to avoid the spiking leakage defects in the back-end process.

### BACKGROUND OF THE INVENTION

1. Field of the Invention

This invention relates to a method for forming a metal oxide semiconductor type field effect transistor (MOSFET), more particularly, to the method for forming the MOSFET by forming a gate and a spacer in a trench. The present invention uses the gate and the spacer, which are formed in the trench of the substrate, of the MOSFET to reduce the junction depth of the source/drain region. The present invention also can reduce the defects in the drain induced barrier lowering (DIBL) and the punch-through leakage to avoid the spiking leakage defects in the back-end process.

2. Description of the Prior Art

In the continual improvement of semiconductor integrated circuit fabrication techniques, the number of devices that can be packed onto a semiconductor chip has increased greatly, while the geometric dimensions of the individual device has been markedly reduced. In today's fabricating process, the feature size has shrunk into the sub-micron range. In such high-density chips, each of the elements' volume must be reduced suitably to decrease the defects of the semiconductor elements, whose volume is reduced.

Referring to FIG. 1, the traditional method for forming the MOSET is to form a gate 20 on a substrate 10. The gate 20 comprises a gate oxide layer 22. Referring to FIG. 2, the N type ions or the P type ions, which are needed in the process, are implanted into the substrate which is on both sides of the gate by using the ions implantation method to form the lightly doped drain (LDD) 30 region. Referring to FIG. 3, the spacer 40 is formed on sidewalls of the gate 20. The material of the spacer 40 is most the insulating material, such as silicon nitride. The main function of the spacer 40 is to reduce the leakage defect of the gate 20. Referring to FIG. 4, the N type ions or the P type ions, which are needed in the process, are implanted into the substrate by using the ions implantation method to form the source/drain 50 region. The source/drain region is located on both sides of the LDD 30 region. Referring to FIG. 5, a silicide layer 60 is formed on the gate 20 and the source/drain region 50 by using the salicide process. Then the traditional MOSFET process is finished.

When the volume of the semiconductor is reduced, the volume of each element is following reduced. When the volume of the MOSFET is reduced, the volume of each element of MOSFET, such as the gate, the spacer or the source/drain region, is also following reduced. When the source/drain region is reduced, the junction depth of the source/drain region is also following reduced. But in the traditional MOSFET structure, the spiking leakage defect and the trade off defect will be caused in the following process after forming the silicide layer if the junction depth of the source/drain region is too shallow. The DIBL defect and the punch-through leakage defect will be caused if the junction depth of the source/drain region is too deep. Therefore, when the volume of the semiconductor element is smaller and smaller, the qualities and yields of the semiconductor elements will be reduced and the production costs will be increased if the traditional method is still used to form the MOSFET.

### SUMMARY OF THE INVENTION

In accordance with the above-mentioned invention backgrounds, the traditional method can not form the MOSFET which has the smaller volume and the better efficacy. The present invention provides a method for forming the MOSFET by forming the gate and the spacer in the trench which is in the substrate to reduce the DIBL defect.

The second objective of this invention is to reduce the punch-through defect by forming the gate and the spacer in the trench which is in the substrate to form the MOSFET.

The third objective of this invention is to reduce the spiking leakage defect by forming the gate and the spacer in the trench which is in the substrate to form the MOSFET.

The fourth objective of this invention is to reduce the trade off defect by forming the gate and the spacer in the trench which is in the substrate to form the MOSFET.

It is a further objective of this invention is to increase the qualities and the yields of the semiconductor elements by forming the gate and the spacer in the trench which is in the substrate to form the MOSFET.

In according to the foregoing objectives, the present invention provides a method for forming the MOSFET by forming the gate and the spacer in the trench which is in the substrate to avoid the DIBL defects and the punch-through leakage defects being caused in the MOSFET, whose volume is reduced, as a result of the too shallow or the too deep junction depth. The present invention can also avoid the spiking leakage defect and trade off defect as a result of the too shallow or the too deep junction depth. The present invention can further increase the qualities and the yields of the semiconductor elements.

### BRIEF DESCRIPTION OF THE DRAWINGS

In the accompanying drawing forming a material part of this description, there is shown:

FIG. 1 shows a diagram in forming a gate on a substrate of a wafer;

FIG. 2 shows a diagram in forming the lightly doped drain region in the substrate;

FIG. 3 shows a diagram in forming the spacers on the sidewalls of the gate;

FIG. 4 shows a diagram in forming the source/drain region in the substrate;

FIG. 5 shows a diagram in forming the silicide layers on the gate and source/drain region;

FIG. 6 shows a diagram in forming a trench in the substrate;

FIG. 7 shows a diagram in forming a gate on the bottom of the trench;

FIG. 8 shows a diagram in forming a spacer layer on the gate and the substrate and filling of the trench;

FIG. 9 shows a diagram in forming the spacers on the sidewalls of the gate and filling of the trench;

FIG. 10 shows a diagram in forming the source/drain region and the source/drain extended region in the substrate;

FIG. 11 shows a diagram in forming a metal layer on the gate, the spacers, and the source/drain region; and

FIG. 12 shows a diagram in forming the silicide layers on the gate and the source/drain region.

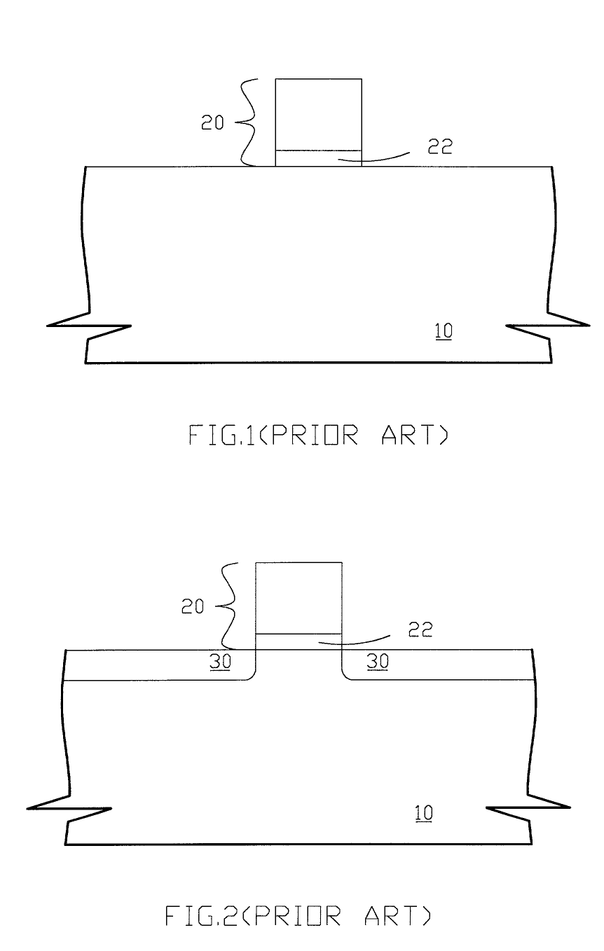

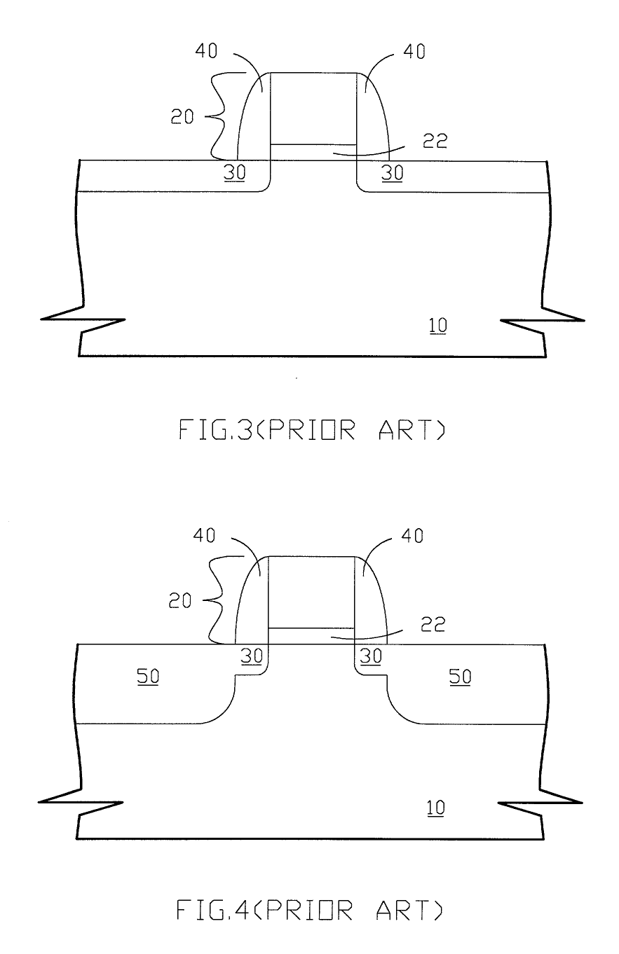

### DESCRIPTION OF THE PREFERRED EMBODIMENT

The foregoing aspects and many of the intended advantages of this invention will become more readily appreciated as the same becomes better understood by reference to the following detailed description, when taken in conjunction with the accompanying drawings, wherein:

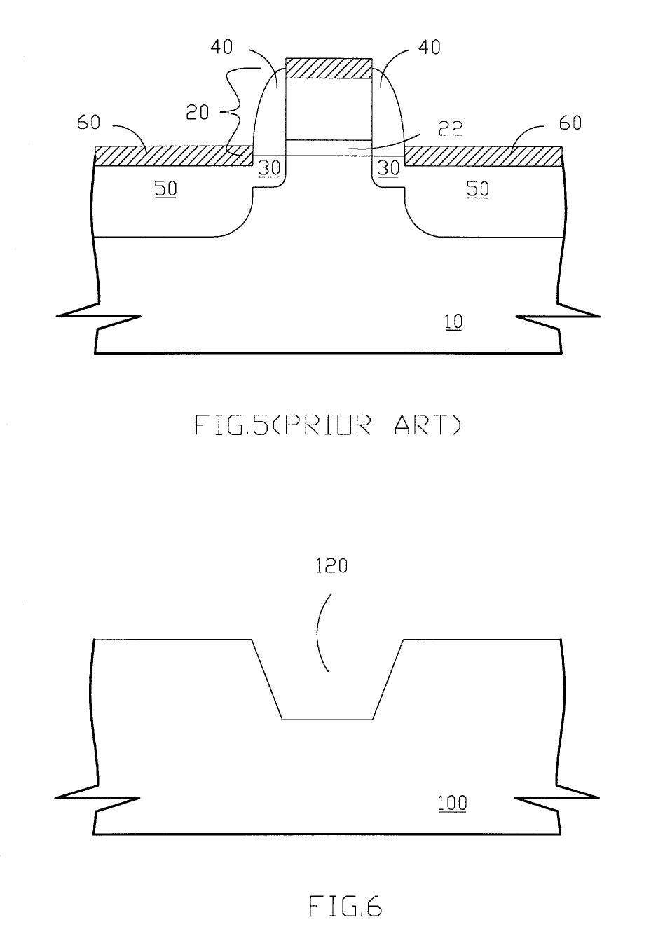

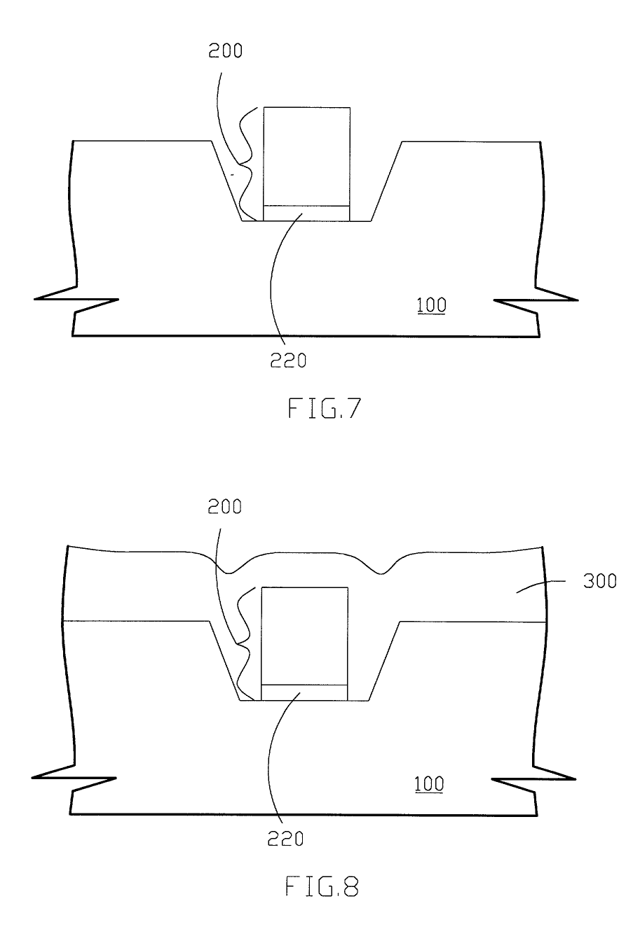

The present invention is to form the MOSFET by forming the gate and the spacer on a trench of the substrate. Referring to FIG. 6, a wafer, which comprises a substrate 100, is provided at first. Then the partial substrate 100 is removed to form a trench 120 in the substrate 100. The width and the depth of the trench 120 are different following the needs of the process. The etching process is most used to remove the partial substrate 100. The silicon substrate is most used to be the material of the substrate 100. Referring to FIG. 7, a gate 200 is formed on the bottom of the trench 120. The gate 200 comprises a gate oxide layer 220. The depth range of the trench is about 50% to 80% of the thickness of the gate. The width range of the trench is about 0.2 μm to 0.35 μm. Following the volume of the semiconductor elements being reduced, the depth and the width of the trench are smaller and smaller. The volume of the gate 200 is reduced following the volume of the MOSFET being reduced. Referring to FIG. 8, then a spacer layer 300 is formed on the gate 200 and the substrate 100 and is filled of the trench. the insulating material is most used to be the material of the spacer layer 300, such as silicon nitride.

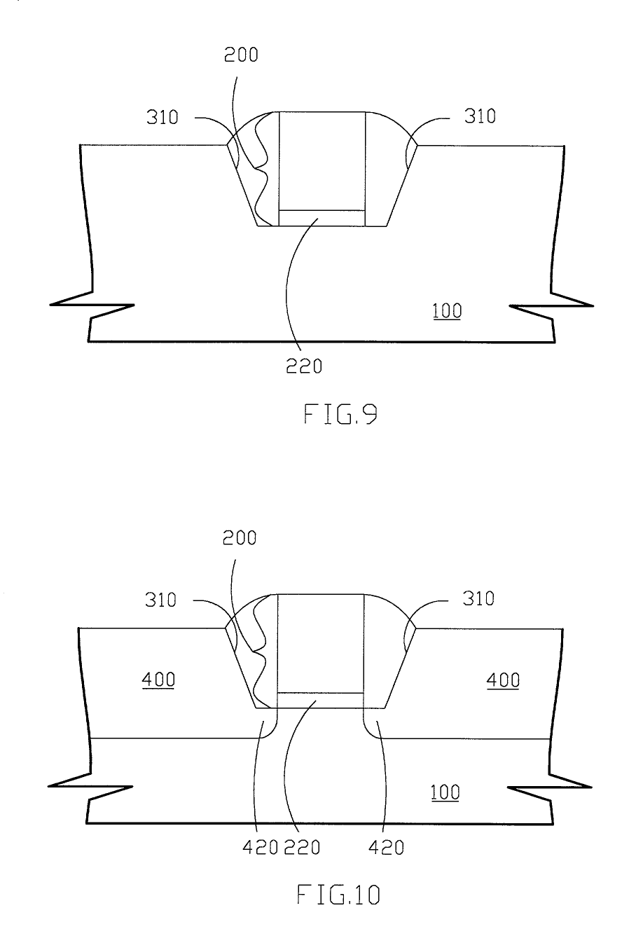

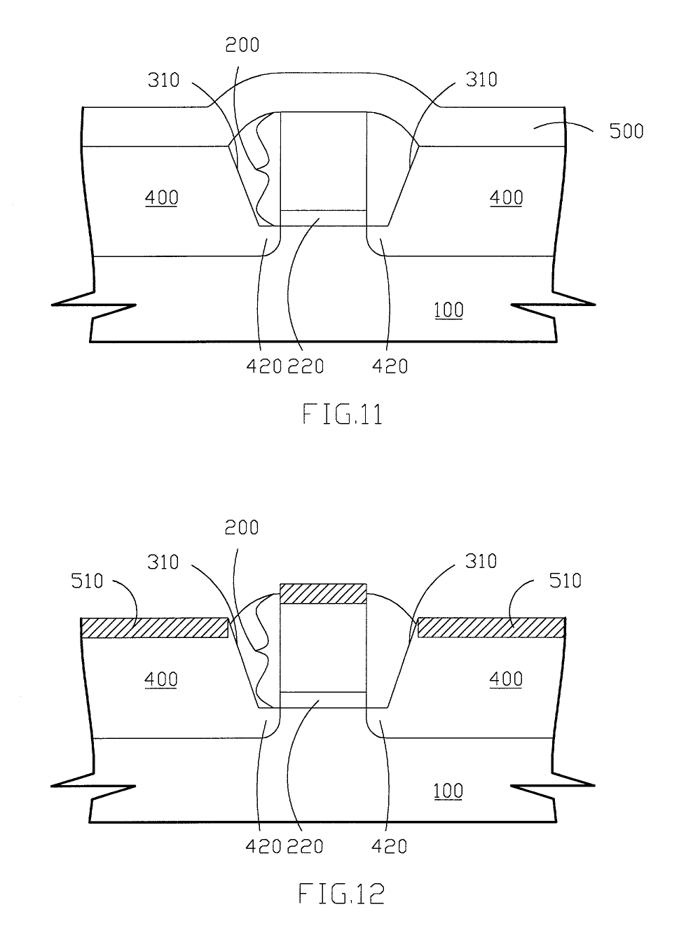

Referring to FIG. 9, the partial spacer layer 300 is removed to form the spacer 310 on the sidewalls of the gate 200. The main function of the spacer 310 is to reduce the leakage defect of the gate 200 and is located on the sidewalls of the gate 200. The spacer 300 is filled of the trench 120. The etching method is most used to remove the partial spacer layer 300. Referring to FIG. 10, then the N type ions or the P type ions, which are needed in the process, are implanted into the substrate, which is on both sides of the spacer, by using the ions implantation method to form the source/drain 400 region. In the traditional method to form the MOSFET, the lightly doped drain region process is most used to avoid the MOSFET having the short channel effects. But after the volume of the MOSFET is reduced, the lightly doped drain region is also following reduced. In the lightly doped drain region process, the range of the lightly doped drain region can be controlled. But in the following high temperature process, the ions, which are in the lightly doped drain region, will move to other regions by the ways of diffusion and permeation to increase the range of the lightly doped drain region and to cause the short channel effect. Therefore, the ions, which are needed in the process, are implanted directly to form the source/drain region 400 in the present invention. Then the first rapid thermal process (RTP) is proceed to be the anneal process. The depth of the ions and the temperature of the RTP process are controlled to make the ions, which are implanted, move to the suitable place by the ways of diffusion and permeation to form the source/drain extended region 420. The function of the source/drain extended region 420 can replace the lightly doped drain region. The temperature of the first rapid thermal process is about 950° C. to 1050° C.

Referring to FIG. 1 1, a metal layer 500 is formed on the gate 200, spacer 310, and the source/drain region 400. The chemical vapor deposition method or the direct current magnetron sputtering method is most used to form the metal layer 500. Then the wafer is placed into the chamber to proceed the second rapid thermal process. The metal layer 500 will react with the silicon, which is at the contact region, to form the silicide layer. The using temperature of the silicide process is about 500 to 700° C. The structure of the metal silicide which is formed in the second rapid thermal process is a metastable C-49 phase structure with higher resistivity. Referring to FIG. 12, the unreacted and the remained metal layer 500 is removed by applying the RCA cleaning method. Therefore, the silicide layers 510 are existed on the top of the gate 200 and the source/drain region 400. Finally, the third rapid thermal process is performed to transform higher resistivity of the C-49 phase silicide structure into lower resistivity of the C-54 phase silicide structure. The using temperature of the third rapid thermal process is about 750 to 850° C. The material of the metal layer 500 can be titanium, cobalt, and platinum. Titanium is usually used to be the material of the metal layer 500.

Titanium is the most common used metallic material for the current salicide process. Basically, titanium is a fine oxygen gettering material, where under an appropriate temperature titanium and silicon at MOSFET device source/drain and gate regions are easily mutually diffused to form a titanium silicide with very low resistance.

The MOSFET, which is formed by using the present invention method, can control the junction depth of the source/drain more accurately and the error in range of the junction depth is greater. Therefore, the spiking leakage defect and the trade off defect will not be caused in the following process after forming the silicide layer if the junction depth of the source/drain region is too shallow. The DIBL defect and the punch-through leakage defect will also not be caused if the junction depth of the source/drain region is too deep. The present invention method can reduce the volume of the semiconductor elements successfully and also can not affect the efficiency of the semiconductor elements. Therefore, the present invention method can increase the qualities and the yields of the semiconductor elements.

In accordance with the present invention, the present invention provides a method for forming the MOSFET by forming the gate and the spacer in the trench which is in the substrate to avoid the DIBL defects and the punch-through leakage defects being caused in the MOSFET, whose volume is reduced, as a result of the too shallow or the too deep junction depth. The present invention can also avoid the spiking leakage defect and trade off defect as a result of the too shallow or the too deep junction depth. The present invention can further increase the qualities and the yields of the semiconductor elements.

Although specific embodiments have been illustrated and described, it will be obvious to those skilled in the art that various modifications may be made without departing from what is intended to be limited solely by the appended claims.

What is claimed is:

1. A method for forming a MOSFET, said method comprises:
providing a wafer, wherein said wafer comprises a substrate;
forming a trench in said substrate;
forming a gate on a bottom of said trench;
forming a spacer on both sides of said gate and filling of said trench;
implanting a ion into said substrate which is on both sides of said spacer;
proceeding a first rapid thermal process to form a source/drain region and a source/drain extended region in said substrate;
forming a metal layer on said gate, said spacer, and said source/drain region;
proceeding a second rapid thermal process to form a silicide layer on said gate and said source/drain region; and
removing said metal layer.

2. The method according to claim 1, wherein said gate comprises a gate oxide layer.

3. The method according to claim 1, wherein a depth of said trench is 50% to 80% of a thickness of said gate.

4. The method according to claim 1, wherein said ion is a N type ion.

5. The method according to claim 1, wherein said ion is a P type ion.

6. The method according to claim 1, wherein said a material of said metal layer is titanium.

7. The method according to claim 1, wherein said a material of said metal layer is cobalt.

8. The method according to claim 1, wherein said a material of said metal layer is platinum.

9. A method for forming a MOSFET, said method comprises:
providing a wafer, wherein said wafer comprises a substrate;
forming a trench in said substrate;
forming a gate on a bottom of said trench, wherein said gate comprises a gate oxide layer;
forming a spacer on a sidewall of said gate and said gate oxide layer and filling of said trench;
implanting a ion into said substrate which is on both sides of said spacer;
proceeding a first rapid thermal process to form a source/drain region and a source/drain extended region in said substrate;
forming a metal layer on said gate, said spacer, and said source/drain region;
proceeding a second rapid thermal process to form a silicide layer on said gate and said source/drain region; and
removing said metal layer and proceeding a third rapid thermal process.

10. The method according to claim 9, wherein a depth of said trench is 50% to 80% of a thickness of said gate.

11. The method according to claim 9, wherein said ion is a N type ion.

12. The method according to claim 9, wherein said ion is a P type ion.

13. The method according to claim 9, wherein said a material of said metal layer is titanium.

14. The method according to claim 9, wherein said a material of said metal layer is cobalt.

15. The method according to claim 9, wherein said a material of said metal layer is platinum.

16. The method according to claim 9, wherein a material of said spacer is silicon nitride.

17. The method according to claim 9, wherein a temperature of said first rapid thermal process is about 950° C. to 1050° C.

18. The method according to claim 9, wherein a width of said trench is about 0.2 μm to 0.35 μm.
